(19) United States
(12) Patent Application Publication
(10) Pub. No.: US 2007/0028838 A1
(43) Pub. Date: Feb. 8, 2007

(54) Gas manifold valve cluster

(76) Inventors: Craig Bercaw, Boulder Creek, CA (US); Dan Cossentine, Santa Cruz, CA (US); Jack Chihchieh Yao, Scotts Valley, CA (US); Tommy Tsz-Kit Lo, Scotts Valley, CA (US); Jay Brian DeDontney, Prunedale, CA (US); Lawrence D. Bartholomew, Felton, CA (US); Robert Hood Chatham III, Scotts Valley, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/496,993

(22) Filed: Jul. 31, 2006

Related U.S. Application Data
(60) Provisional application No. 60/703,711, filed on Jul. 29, 2005.
(60) Provisional application No. 60/703,717, filed on Jul. 29, 2005.
(60) Provisional application No. 60/703,723, filed on Jul. 29, 2005.

(51) Int. Cl. C23C 16/00; C23C 14/00

(52) U.S. Cl. 118/715; 118/50; 118/719

(57) ABSTRACT

The present invention relates generally to a deposition apparatus for semiconductor processing. More specifically, embodiments of the present invention relate to a gas manifold valve cluster and deposition apparatus. In some embodiments of the present invention a gas manifold valve cluster and system are provided that promotes reduced length and volumes of gas lines that will be exposed to atmosphere during cleaning which minimizes the time required to perform process chamber maintenance and therefore increase the productivity of the process chamber. In other embodiments a gas manifold valve cluster and ALD deposition apparatus are provided.

### CROSS REFERENCE TO RELATED APPLICATIONS

This application claims the benefit of, and priority to, U.S. Provisional Patent Application Ser. No. 60/703,711 filed on Jul. 29, 2005, 60/703,717 filed on Jul. 29, 2005 and 60/703,723 filed on Jul. 29, 2005, the entire disclosures of all of which are hereby incorporated by reference. This application is related to co-pending United States Utility Patent Application corresponding to Attorney Docket no. 186440/US/2/MSS, filed concurrently herewith, the entire disclosure of which is hereby incorporated by reference.

### FIELD OF THE INVENTION

The invention relates generally to a deposition apparatus for semiconductor processing. More specifically, the invention relates to a gas manifold valve cluster and deposition apparatus useful to perform various process methods to form thin films on a semiconductor substrate.

### BACKGROUND OF THE INVENTION

The manufacture of semiconductor devices requires many steps to transform a semiconductor wafer to an ensemble of working devices. Many of the process steps involve methods that are adapted to be practiced on one substrate at a time. These are known as single wafer processes. The process chambers used to practice these methods are known as single wafer chambers and should be distinguished from batch process chambers wherein a plurality of substrates may be processed simultaneously. Single wafer process chambers are often grouped together in a cluster tool that allows for the possibilities of either simultaneously practicing the same process methods on a number of substrates in parallel or practicing a number of process methods sequentially within the same cluster tool.

A number of process methods are well suited to be practiced in single wafer process chambers. Examples of these process methods include, but are not limited to: chemical vapor deposition (CVD), atomic layer deposition (ALD), physical vapor deposition (PVD), Epi, etching, ashing, rapid thermal processing (RTP), short thermal processes such as spike anneal, and the like. These methods often include an energy source to facilitate processing, particularly thermal processing. Examples of these energy sources comprise thermal, plasma, photonic, and the like. The detailed configuration of these various types of process chambers will be determined by the requirements of the process method and the desired result of the process step.

Cost of Ownership (COO) in dollars/wafer is a major consideration in the selection of semiconductor process equipment. The calculation of COO is very complex. One of the input variables is the uptime of the equipment. Uptime is dependent upon factors such as system reliability, time between manual cleans, manual clean time, requalification time, and the like. Most of the process methods cited above are practiced at elevated temperatures, low pressures, and require the exchange of several gaseous species during the various steps of the method. Therefore, details such as process chamber volume, process chamber materials, integration of energy sources, gas introduction means, exhaust means, and the like are critical in determining the success of the process method.

A process chamber design for the deposition of a thin film by Atomic Layer Deposition (ALD) will be used as an example. A substrate or wafer is typically supported on a substrate support and is heated to a temperature in the range of 100° C. to 600° C. A gas distribution apparatus, such as a showerhead injector, is placed above the substrate. The showerhead injector contains a plurality of holes to distribute gases across the surface of the wafer. A horizontal plate or ring is sometimes placed around the substrate support and loosely defines the bottom of the reaction volume. In such prior art systems this reaction volume is relatively large. The plate may contain a plurality of holes that allows the gas to be exhausted from the process chamber through a single exhaust port that is usually found in the lower portion of the process chamber, below the plane of the substrate. Additionally, it is common in the art for the plate to be located below the wafer transport plane. One major drawback of this configuration is that the slot valve and wafer transfer region through which the wafers are transported are also exposed to the reaction zone. This results in the deposition of materials, particles, and contaminants in the slot valve region. This also results in plasma field asymmetries for process methods that use a plasma energy source. Further, this wafer transfer region causes temperature non-uniformities during processing. The region tends to have a black body cavity effect and the area of the heater that is adjacent this region develops cold regions, thus causing uneven heating and processing of the wafer.

Thus, known process chamber designs suffer from a number of shortcomings. Reaction volumes tend to be excessively large relative to the volume of the cylinder defined by the diameter of substrate support. The walls of such process chambers are often not symmetrical due to the requirement for additional ports, substrate transfer openings and the like. Power from energy sources such as thermal, plasma, and photonic sources reach the walls of the process chamber and facilitate the actions of the process method outside the areas which are directly above the substrate. This leads to undesirable effects including one or more of: long evacuation times, excessive chemical usage, long purge times, long cycle times for ALD process methods, asymmetric gas flow, particle generation, asymmetric plasma densities for plasma process methods, material deposits on the walls of the process chamber, shorter times between cleaning the process chamber, and the like.

The process chamber must be opened for periodic cleaning and maintenance. This time is costly in that the process chamber is not productive during the maintenance period. One of the operations in preparation for opening the chamber is removing and purging the reactive gases from the portions of the gas lines that will be exposed to the atmosphere while the process chamber is open. This operation involves a “cycle/purge” procedure that involves alternately evacuating the gas line with a vacuum pump and then flowing an inert gas such as nitrogen through the gas line. This procedure must be repeated many times (typically 20 or more) for each gas line.

While the gas line is exposed to atmosphere during the process chamber maintenance period, the internal surfaces of the gas line will absorb a thin film of water from the moisture in the air. This will be true even if an inert gas such as nitrogen is allowed to flow through the gas line throughout the maintenance procedure. This thin film of water must be removed from the internal surface of the gas line before the reactive gases are reintroduced to the gas line after the maintenance procedure is completed. The thin film of water is typically removed through the same “cycle/purge” procedure described above. The length of time for each portion of the cycle/purge procedure and the number of cycle/purge steps for both of these procedures will be strongly influenced by the length and volume of the gas lines.

There are currently many designs of single wafer process chambers used in the manufacture of semiconductor devices. These designs suffer from several drawbacks. Examples of the drawbacks include any one or more of: long gas line lengths, large gas line volumes, large reaction zone volumes, slow gas exchange times, asymmetrical plasma densities, long process chamber overhead times, and the like.

Given the many limitations of known deposition apparatus designs, there is a need for further developments in the design of deposition apparatus and components suitable for semiconductor processing.

### BRIEF SUMMARY OF THE INVENTION

The present invention relates generally to a deposition apparatus for semiconductor processing. More specifically, embodiments of the present invention relate to a gas manifold valve cluster and deposition apparatus. In some embodiments of the present invention a gas manifold valve cluster and system are provided that promotes reduced length and volumes of gas lines that will be exposed to atmosphere during cleaning which minimizes the time required to perform process chamber maintenance and therefore increase the productivity of the process chamber. In other embodiments a gas manifold valve cluster and system are provided that promote fast actuation of gases during semiconductor processing, particularly during atomic layer deposition (ALD). In some embodiments of the present invention, chemical precursor pulse times in an ALD cycle have been reduced by up to 50% as compared to prior art pulse times.

Embodiments of the present invention may be used to practice process methods on a semiconductor substrate, such as but not limited to: thin film deposition techniques such as CVD, PVD, and ALD, etching, ashing, cleaning, and the like. In some embodiments the gas manifold valve cluster and system promote one or more of: more efficient use of the gas, reduction in the sources of contamination, facilitating uniform gas flow pattern, facilitating fast gas exchange, and easier chamber cleaning.

In an exemplary embodiment, a deposition apparatus for processing a substrate in a process chamber is provided, comprising: one or more gas supply sources; a gas manifold valve cluster positioned proximate to the process chamber and comprising a gas valve for each gas; and a chamber lid gas supply line extending from the gas manifold valve cluster to a gas distribution device.

In some embodiments, a deposition apparatus for processing a wafer is provided, comprising: a wafer support for holding a wafer; a wafer transfer region where the wafer is conveyed by a robot transfer device through an opening in a wall of the process chamber and onto the wafer support; a gas distribution device positioned above the wafer; a baffle ring formed within the apparatus and encircling the wafer support and having a plurality of apertures formed therein, said baffle ring being configured to separate a reaction zone from an exhaust region; a gas manifold valve cluster positioned proximate and outside of said apparatus and comprising a gas valve for each gas and a chamber lid gas supply line extending from said gas manifold valve cluster to the injector; and the wafer support being movable in the vertical direction toward the gas distribution device to raise the substrate above the level of the wafer transfer region and opening in the wall of the process chamber, and said wafer support cooperates with the baffle ring to define the reaction zone having reduced volume. In some embodiments the gas manifold valve cluster is mounted on the outside of the apparatus or process chamber. Is some embodiments the deposition apparatus further comprises a chamber lid assembly, and the gas manifold valve cluster is coupled to said chamber lid gas supply line by a connection point comprising a seal and being detachable from said lid to permit opening of said lid.

In further embodiments an ALD deposition apparatus for processing a wafer is provided, comprising: a process chamber housing a wafer support; an injector for conveying gases to the wafer; a baffle ring encircling the wafer support, said wafer support, injector and baffle ring defining a reaction zone where the wafer is processed, said reaction zone being isolated from a region where the wafer is moved in and out of the process chamber; a gas manifold valve cluster positioned proximate and outside of said deposition apparatus and comprising a gas valve for each gas, and a chamber lid gas supply line extending from said gas manifold valve cluster to the injector; and a gas exhaust plenum encircling the baffle ring and in fluid communication with apertures formed in the baffle ring, said gas exhaust plenum being configured to exhaust gases from the reaction zone over substantially 360 degrees.

### BRIEF DESCRIPTION OF THE DRAWINGS

These and various other features and advantages of the present invention will be apparent upon reading of the following detailed description in conjunction with the accompanying drawings and the appended claims provided below, in which:

FIG. 1 is a cross sectional simplified view of one embodiment of the gas manifold valve cluster and deposition apparatus;

FIG. 2 is a three-dimensional exploded view of the gas manifold valve cluster and deposition apparatus according to embodiments of the present invention;

FIG. 3 is an exemplary embodiment of a gas schematic according to embodiments of the present invention

FIG. 4 is a cross section simplified view of one embodiment of the deposition apparatus of the present invention showing a wafer support in the down position;

FIG. 5 is a cross section simplified view of one embodiment of the deposition apparatus of the present invention showing a wafer support in the up position; and

FIG. 6 is a top plan view illustrating embodiments of the gas manifold valve cluster and deposition apparatus of the present invention.

### DETAILED DESCRIPTION OF THE INVENTION

The present invention relates generally to a deposition apparatus for semiconductor processing. More specifically, embodiments of the present invention relate to a gas manifold valve cluster and deposition apparatus.

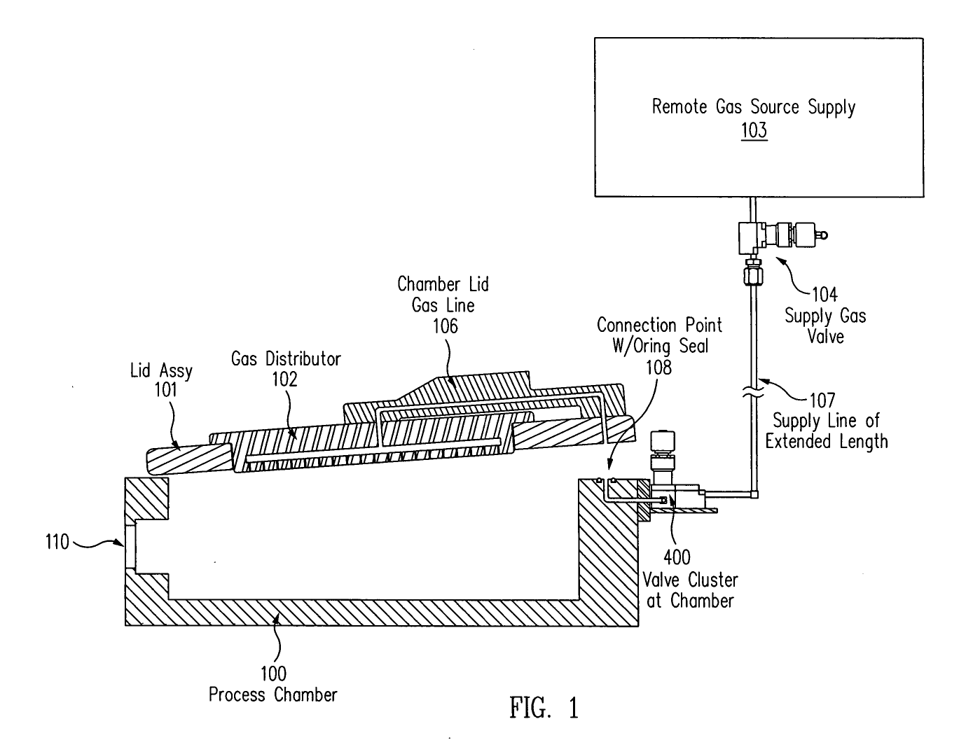

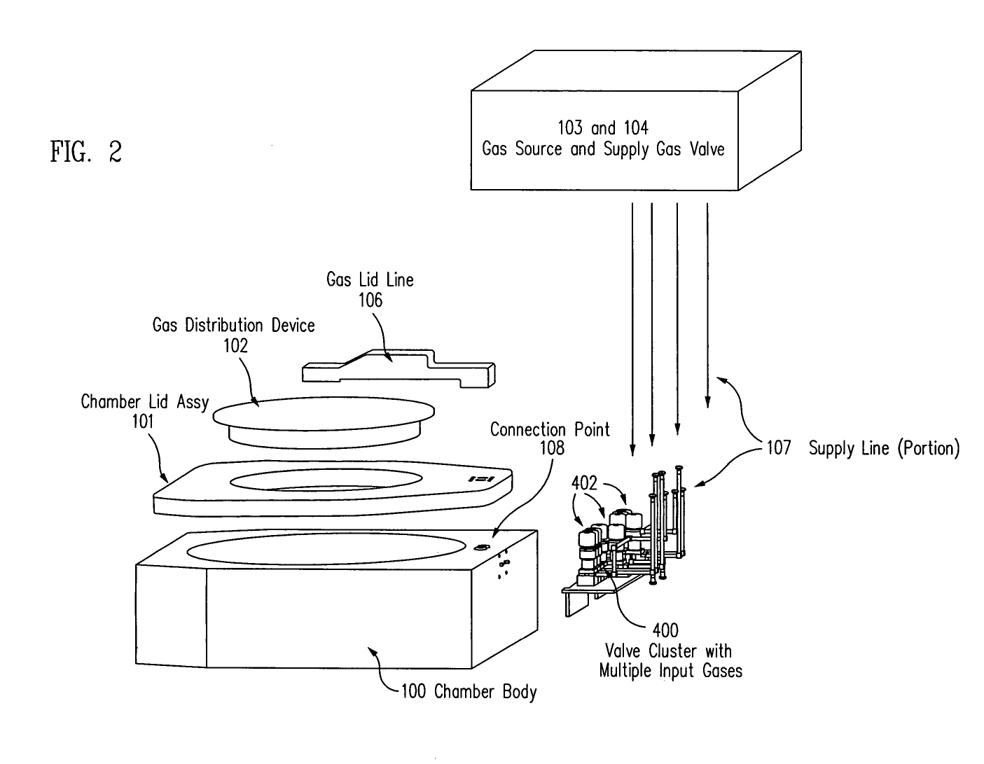

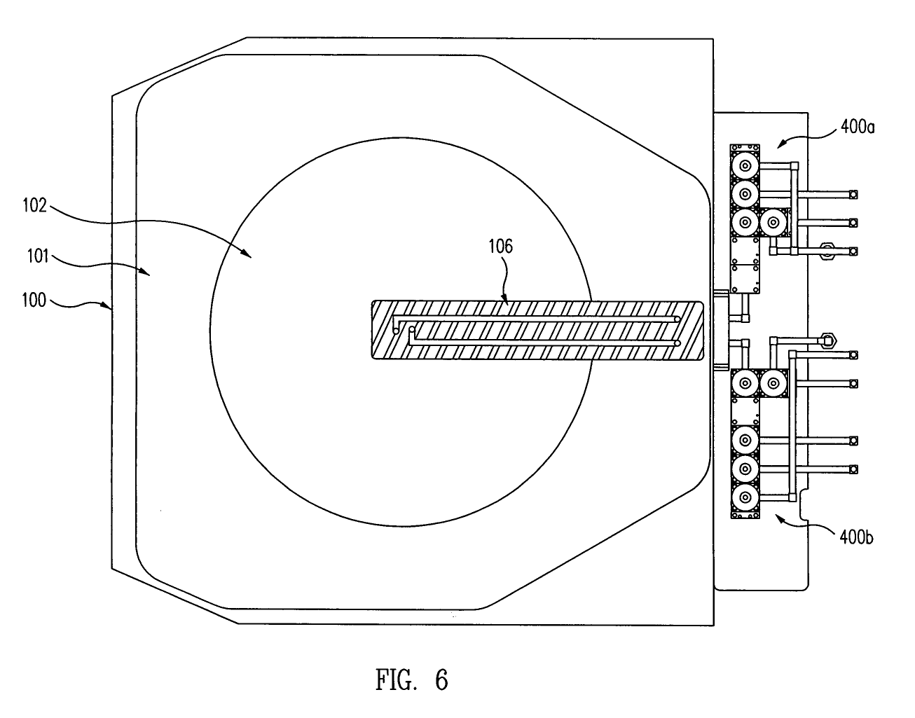

FIG. 1 illustrates a cross sectional simplified view of one embodiment of the gas manifold valve cluster and deposition apparatus of the present invention. FIG. 2 depicts a three-dimensional exploded view of embodiments of the gas manifold valve cluster and deposition apparatus of the present invention. FIG. 6 shows a top plan view of embodiments of the gas manifold valve cluster and deposition apparatus It will be appreciated by those skilled in the art that embodiments of the present invention are applicable to a wide variety of process methods such as chemical vapor deposition (CVD), atomic layer deposition (ALD), physical vapor deposition (PVD), Epi, etching, ashing, rapid thermal processing (RTP), short thermal processes such as spike anneal, and the like.

Referring to FIGS. 1 and 2, a substrate (not shown) is supported inside process chamber 100. Process chamber or chamber body 100 generally includes a wafer support (not shown) for supporting wafer and a gas distribution device 102, such as an injector, for delivering gases to the substrate for processing. Process chamber 100 further includes removable chamber lid assembly 101, having chamber lid gas line 106 formed therein. Chamber lid assembly 101 may be heated. Located proximate to the process chamber is gas manifold valve cluster 400. Gas manifold valve cluster 400 is coupled a remote gas source supply 103 via one or more supply lines and associated gas supply valves 104.

Of particular advantage, gas manifold valve cluster 400 is positioned near, but outside of process chamber 100. In some embodiments, gas manifold valve cluster 400 is mounted on the process chamber 100, such as on the back of the process chamber.

Gas is introduced into the process chamber 100 and to the substrate through gas distribution device 102. Gas distribution device 102 may be comprised of a single inlet, an injector, a showerhead injector, a gas ring, or the like. Gas distribution device 102 may be powered depending on the requirements of the particular process method to be practiced.

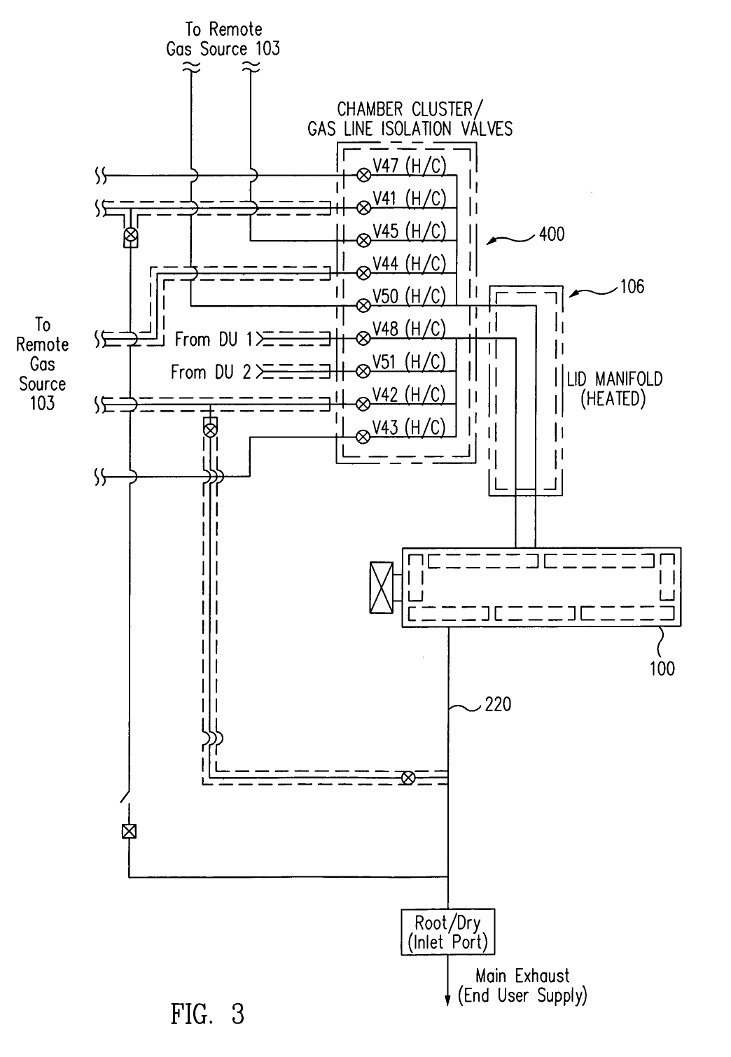

One or more gases are supplied to process chamber 100 from remote gas source 103. There is typically a supply gas valve 104 situated near or inside gas source 103. For simplicity, only a single pair of gas source 103 and associated supply gas valve 104 is shown. However, there will be a similar configuration for each gas supplied to the process chamber, as illustrated in the gas schematic shown in FIG. 3. Gas is conveyed from supply gas valve 104 to gas manifold valve cluster 400 through supply gas line 107. Gas manifold valve cluster 400 includes a plurality of valves 402 (FIG. 2) each of which is dedicated to a supply gas valve. Gas manifold valve cluster 400 is situated in close proximity to chamber 100 and the piping length from the gas distribution device 102 to the valves is substantially reduced.

In some embodiments, gas manifold valve cluster 400 communicates with chamber lid gas line 106, at a connection point 108. Connection point 108 includes an o-ring seal or other suitable sealing means, and is configured to allow the opening of chamber lid assembly 101. This promotes easier maintenance.

In some embodiments incompatible gas mixtures may be employed. In such an instance, two isolated valve clusters 400a and 400b may be used as illustrated in FIG. 6. In this embodiment, chamber gas line 106 comprises two separate gas delivery lines which independently deliver the gases to two separate gas path networks in gas delivery device 102. The isolated valve clusters 400a and 400b are coupled to the chamber gas line 106 via separate associated connection points.

During processing gas manifold valve cluster 400 is actuated to convey desired gases through point 108 and chamber lid gas line 106 and to the injector 102. The length of gas line that must be cycle/purged during processing is advantageously minimized. Additionally, for maintenance, chamber lid gas line 106 is most effected by deposits and build-up and can be cleaned and serviced easily according to the present invention. In some embodiments, chamber lid gas line 106 is manufactured from a material that results in very uniform heating to prevent “cold spots” in the gas delivery system. This is especially beneficial for gases with low vapor pressures. Additionally, fresh reactant gas can be supplied inside supply gas line 107 while waiting for maintenance to be completed. This further decreases the time required to perform maintenance on the process chamber and increases the overall system productivity.

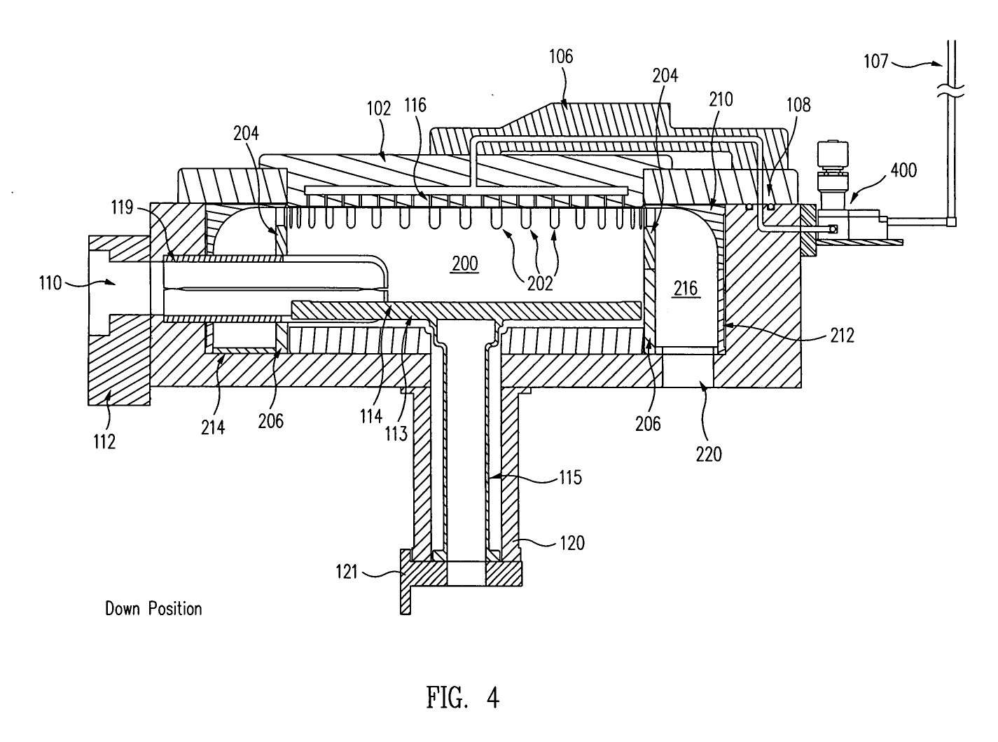

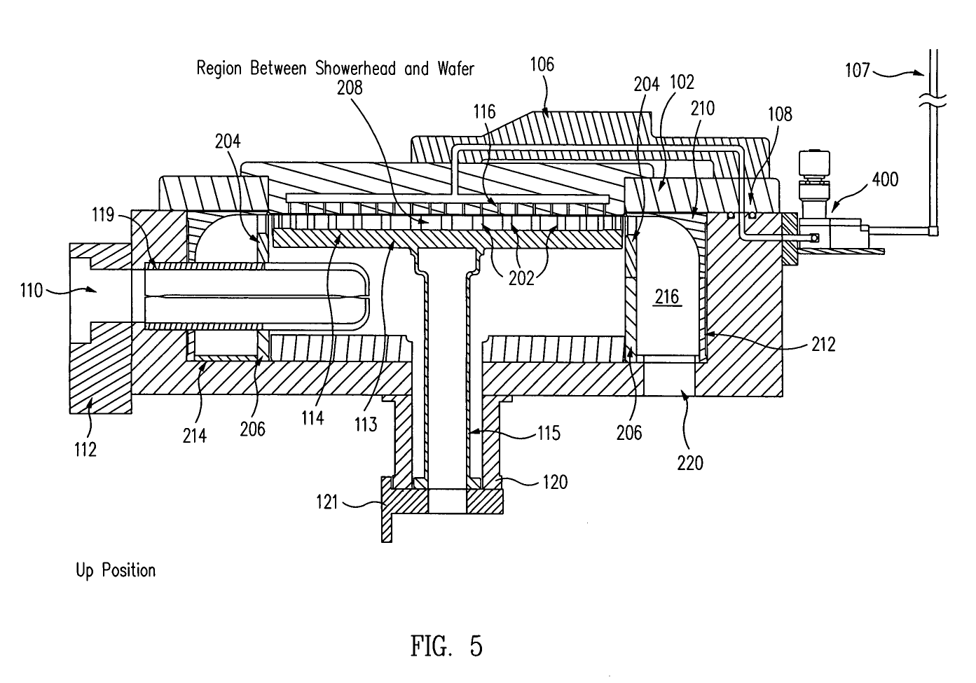

Referring to FIGS. 4 and 5 another embodiment of the present invention is shown. In general deposition apparatus includes process chamber 100 that encloses a volume and includes a gas distribution device 102 coupled to gas manifold valve cluster 400 via chamber lid gas line 106 and connection point 108 for conveying gases to the process chamber, wafer support 113 adapted to support a wafer or substrate 114 for processing, and baffle ring 200 encircling the wafer support 103, which together form a reaction zone or volume 208. In some embodiments, the deposition apparatus is as described in more detail in U.S. Utility patent application Ser. No. 11/______ (Attorney Docket no. 186440/US/2/MSS), filed concurrently herewith, the entire disclosure of which is hereby incorporated by reference.

Typically a robotic transfer device (not shown) moves a wafer through a slot valve 112 through the wall of the process chamber body 100 and into wafer transfer region 110. The wafer is placed on the wafer support 114, or on pins protruding through wafer support 113. The process chamber 100 is exhausted by a vacuum pump (not shown) through an exhaust port 220.

Gases are introduced to process chamber 100 through gas distribution device 102. Gas distribution device 102 may be comprised of any suitable gas delivery device; and may be comprised of for example: a single inlet, one or more injectors, a showerhead injector, a gas ring, or the like. Gas distribution device 102 may be powered depending on the requirements of the particular process method to be practiced. In an illustrative embodiment gas distribution device 102 is comprised of a showerhead type injector and includes a plurality of injector ports or orifices 116 spaced across a gas delivery surface of the injector. In another embodiment, gas distribution device 102 is comprised of an injector as described in U.S. Pat. No. 6,921,437, the entire disclosure of which is hereby incorporated by reference, which permits the delivery of two gases to the reaction zone 208 via independent gas path distribution networks.

Gases are conveyed to gas distribution device 102 by chamber lid gas line 106 coupled to gas manifold valve cluster 400 for fast deliver and actuation of gases.

Wafer support 113 is configured to support wafer 114 during processing. Wafer support 113 generally includes a top surface having a pocket formed therein which receives and secures the wafer 114. Lift pin guides may be formed in the wafer support for receiving lift pins. Lift pins are typically extended above the surface of the wafer support to receive a wafer from a wafer transfer robot (not shown) and then retracted so that the wafer is seated in a pocket formed in the surface of wafer support 113 for processing. Lift pins may be configured for independent movement. Alternatively, lift pins may be stationary, and are extended and retracted by vertical movement of the wafer support 113.

The wafer support 113 may be heated and/or cooled via heater elements and/or cooling passages (not shown) formed in the body of the support. In some embodiments, wafer support 113 may be comprised of a stage heater. In other embodiments the wafer support may be comprised of an electrostatic chuck, and may be grounded or powered depending on the requirements of the particular process method to be practiced. Other energy sources may be provided, such as a plasma source, radiant heat lamps, UV source, and the like, and such other energy sources may be located at suitable locations within the process chamber 100.

In some embodiments wafer support 113 is supported by a shaft assembly which is adapted to travel in the z-axis. The shaft assembly may also impart rotation to substrate support 113 if desired. In the exemplary embodiment shaft assembly is generally comprised of shaft 115 which is coupled to wafer support 113 and is actuated by sealed flexible bellows 120 and vertical motion coupler 121. While one particular embodiment of shaft assembly is shown, many other types of assemblies that provide z-axis travel may be used within the scope of the invention.

Z-axis travel of the shaft raises and lowers the wafer support 113. FIG. 4 illustrates deposition apparatus 100 when the shaft 115 and wafer support 113 are in the down, or lower, position. FIG. 5 depicts deposition apparatus 100 when the shaft 115 and wafer support 113 in the up, or raised, position. In the exemplary embodiment flexible bellows 120 mates between the bottom of the process chamber and vertical motion coupler 121. This placement permits changes in reaction zone volume 208 by changing the wafer support 113 height position within the process chamber, yet while maintaining an isolating seal between the outside atmosphere and the interior of the process chamber. According to embodiments of the present invention, process chamber 100 is configured for processing when wafer support 113 and shaft 115 are in the raised position. When in the raised position as shown in FIG. 5, substrate support 113 cooperates with baffle ring 200 and gas distribution device 102 to define a reaction zone 208 having reduced volume. Notably, wafer transfer area 110 and slot valve 112 are not within the reduced reaction zone 208. Wafer transfer area 110 and slot valve 112 are below the wafer support 113, and thus do not impact the wafer 114 during processing.

During processing, this substantial reduction in the volume of reaction zone 208 promotes faster processing time since a much smaller volume must be exhausted between ALD pulse processing steps. Moreover, this reduced reaction zone promotes more uniform distribution of gases. Additionally, since transfer area 110 and slot valve 112 are below the wafer support 103, the wafer 104 is not subjected to black body effects nor is the heating and temperature uniformity disrupted, as is a common problem in prior art systems.

Of particular advantage, embodiments of the deposition apparatus of the present invention employ baffle ring 200. Since exhaust port 220 is usually at a single location in the bottom of the apparatus 100, asymmetric gas flow in the reaction zone 208 may occur. Such asymmetric gas flow can lead to non-uniformities in the heating and deposition of films on the surface of the wafer during processing. Embodiments of the present invention address this problem. As illustrated in FIGS. 4 and 5 baffle ring 200 generally encircles the wafer support 103 and in the exemplary embodiment is comprised of an upper portion 204 and a lower portion 206. A plurality of baffle holes or orifices 202 are formed in the upper portion 204 of baffle ring 200. Baffle holes 202 allow unreacted or byproduct gases to flow from the reaction zone 208 into exhaust plenum 216. Baffle holes 202 are preferably spaced around the substantial circumference of the baffle ring 200 so to form an exhaust path for gases around the substantial to entire periphery of the wafer. This promotes substantially symmetric flow of gases from the wafer, and permits the exhausting of gases over 360 degrees.

Baffle holes 202 may be configured to be different sizes to compensate for the flow asymmetries in reaction volume 208 and/or to be tailored to specific applications and processes. In some embodiments, baffle holes 202 cause a flow restriction that creates a local pressure drop which promotes more uniform gas distribution across the wafer. Baffle holes 202 may be equally spaced around the substantial to entire circumference of the baffle ring 200. Alternatively, baffle holes 202 may be unequally spaced around the substantial to entire circumference of baffle ring 200 in order to selectively distribute the gases. The preferred number, geometric shape, size and distribution of baffle holes 202 may be selected based on the particular application or requirement of the process and may be determined by routine experimentation. Examples of suitable geometric shapes comprise slits, slots, rectangles, circles, triangles, trapezoids, and the like.

During processing, when the wafer support 113 is in the up, or raised position, the top surface of the wafer 114 is preferably positioned adjacent the baffle holes 202 to promote substantially symmetrical exhausting of unreacted gases and by-products. In one embodiment where the baffle holes are comprised of a slot, the top surface of the wafer is positioned adjacent the center-line of the bottom radius of the slot. Of course, other orientations are possible and are within the scope of the present invention.

The upper potion of baffle ring 200, also referred to as upper baffle ring 204, is made of a material comprising metals, metal alloys, ceramics, glasses, polymers, composites, or combinations thereof. The selection of the material will generally be driven by process requirements and cost of materials. Preferably, upper baffle ring 204 is composed of a ceramic. In some embodiments, top surface of upper baffle ring 204 mates with upper chamber shield 210 which is usually made of a similar material and serves to decrease the deposits of material on the lid 106 of deposition apparatus 100. Further, if a plasma process is used this configuration is useful in the confinement of the plasma density for plasma-based process methods. Upper baffle ring 204 is supported by the lower portion of the baffle ring 200, also referred to as lower baffle ring 206.

Lower baffle ring 206 has a slot or opening (not shown) that cooperates with substrate transfer area 110 to allow substrates to be transported into the deposition apparatus and placed on substrate support 103. This configuration allows lower baffle ring 206 to be manufactured from a less expensive material in those cases where upper baffle ring 204 is composed of an exotic, expensive material. Lower baffle ring 206 may be made from a material comprising metals, metal alloys, ceramics, glasses, polymers, composites, or combinations thereof. Preferably, lower baffle ring 206 is comprised of a simple metal, such as aluminum. In the exemplary embodiment, upper baffle ring 204 is shown as a simple cylinder, but the shape of upper baffle ring 204 may comprise cylinders, cones, polygons, or combination thereof.

In one embodiment of the present invention, the baffle ring assembly is made from 2 pieces, upper baffle ring 204, and lower baffle ring 206. Upper baffle ring 204, and lower baffle ring 206, may be made of the same material or may be made of different materials. Examples of the materials comprise metals, metal alloys, ceramics, glasses, polymers, composites, or combinations thereof.

In another embodiment of the present invention, the baffle ring 200 is made from a single piece formed by the fusion of upper baffle ring 204, and lower baffle ring 206. The single-piece baffle ring may be made of a variety of materials. Examples of the materials comprise metals, metal alloys, ceramics, glasses, polymers, composites, or combinations thereof.

In yet another embodiment of the present invention, baffle ring 200 is made from a single piece formed by the fusion of upper baffle ring 204 and lower baffle ring 206 and where upper shield 210 is been combined with the upper baffle ring 204 into a single part. The single-piece baffle ring assembly may be made of a variety of materials. Examples of the materials comprise metals, metal alloys, ceramics, glasses, polymers, composites, or combinations thereof.

Further, while the exemplary embodiments illustrated in the Figures show baffle ring 200 comprised of two pieces 204 and 206, either mated or fused, it should be understood that baffle ring 200 may alternatively be formed of a single ring.

Embodiments of the present invention provide for substantially symmetrical exhausting of gases from the deposition apparatus. Deposition apparatus 100 further includes gas exhaust plenum 216. Exhaust plenum 216 preferably is comprised of an annular space or channel that extends around the substantial circumference of the reaction zone 208 to promote symmetrical exhausting of gases from the reaction zone. In an exemplary embodiment, exhaust plenum 216 is formed by baffle ring 200 and a plurality of chamber shields, specifically upper chamber shield 210, lower chamber shield 212 and floor chamber shield 214 which are spaced apart from baffle ring 200 and which generally follow the general contour of baffle ring 200 to form there between an annular space. Gases exit the reaction zone 208 via baffle holes 202 and enter gas exhaust plenum 216, where the gases are then exhausted from the deposition apparatus 100 through vacuum pump port 220.

Upper chamber shield 210 forms the top of exhaust plenum 216, and in some embodiments upper chamber shield 210 may abut the chamber lid 101 to form, in part with gas distribution device 102 the top of the reaction zone 208. Similar to the upper baffle ring 204 as described above, upper chamber shield 210 may be formed of specialized materials, particularly when upper chamber shield 210 is exposed to the reaction zone 208.

Lower chamber shield 212 generally forms the outer wall of exhaust plenum 216, while baffle ring 200 forms the inner wall of exhaust plenum 216. In one embodiment, lower chamber shield 212 has a slot or opening (not shown) that cooperates with substrate transfer area 110 to allow substrates to be transported into the deposition apparatus and placed on substrate support 113. The opening in lower chamber shield 212 may have a similar contour and shape as the opening in lower baffle ring 206. Moreover, similar to lower baffle ring 206 as described above, lower chamber shield 212 may be formed of a different, and less expensive material, than upper chamber shield 210.

An opening in lower baffle ring 206 and the opening in lower chamber shield 212 are adapted to receive slot valve shield 119 which permits the transfer of a wafer 114 in and out of the deposition apparatus 100 through the wafer transfer area 110, while maintaining isolation the gas exhaust plenum 216. In some embodiments, upper baffle ring 204 and upper chamber shield 210 each also include an opening (not shown) which cooperate with the openings in the lower baffle ring 206 and lower chamber shield 212 to accommodate the slot valve shield 114. Of particular advantage and in contrast to prior art apparatus, this permits the full, symmetrical exhausting of the gases over 360 degrees while isolating the reaction zone 208 from the wafer transfer region.

Chamber floor shield 214 generally forms the floor of exhaust plenum 216, and in the exemplary embodiment extends a full 360 degrees. Floor shield 214 may be comprised of any suitable material, and since it is not exposed to the reaction zone, floor shield 214 may be comprised of a different material than upper chamber shield 210.

As illustrated in the exemplary embodiment, chamber shields 210, 212 and 214 are formed of separate pieces. This allows for flexibility in material selection, and further allows for faster cleaning of the deposition apparatus since each of the shields may be removed and cleaned and/or serviced independently, without having to take the entire process chamber 100 out of service. However, it should be understood that other embodiments are within the scope of the present invention. For example, in some embodiments all three shields may be formed of a single piece. Additionally, in another alternative embodiment, the lower chamber shield and chamber floor shield may be formed of a single piece.

The deposition apparatus of the present invention is particularly suited to carry out atomic layer deposition (ALD) processes. In general, ALD comprises conveying a first pulse of a precursor to the reaction zone where it forms a monolayer on the surface of the substrate. Excess amounts of the first precursor is then removed by techniques such as purging, evacuation, or combinations thereof. A next pulse of a reactant is then introduced and allowed to react with the monolayer of the first precursor to form the desired material. Excess amount of the reactant is then removed by techniques such as purging, evacuation, or combinations thereof. The result is the deposition of a single monolayer of the desired material. This sequence is repeated until the desired thickness of the target material has been deposited.

As described above, baffle ring 200, gas distribution device 102 and the substrate support 113 when in the raised position as illustrated in FIG. 5 all define a very small reaction volume 208. Note that the chamber lid gas line 106, connection point 108 and gas manifold valve cluster 400 are all removed in this view for clarity. This reduced reaction zone promotes one or more of: lower chemical usage, greater chemical efficiency, faster gas purge and evacuation times, faster gas exchange times, and the like. Embodiments of the present invention further promote higher throughput and lower cost of ownership for the semiconductor process equipment. Additionally, baffle ring 200 promotes confinement of an energy source, such as thermal energy or plasma energy, into reaction volume 208. This promotes fewer deposit build-up, lower particle contamination on the wafers, and increased time intervals between when the process chamber has to opened to be cleaned. Embodiments of the present invention also minimize the deposition of materials, by-products, or particles in the wafer transport area 110, since such area is not within the reduced reaction zone 208.

Experiments conducted using embodiments of the present invention exhibit lower chemical usage and uniformity. In one example, deposition of an aluminum oxide film Al₂O₃ was conducted by ALD from trimethyl aluminum (TMA) and water. Deposition rate was maintained while reducing the time and amount of precursors used to practice the method carried out in embodiments of the deposition apparatus of the present invention. Additionally, the uniformity of the deposited film is improved over prior art systems. In some embodiments of the present invention, chemical precursor pulse times in an ALD cycle have been reduced by up to 50% as compared to prior art pulse times.

The foregoing descriptions of specific embodiments of the present invention have been presented for the purpose of illustration and description. They are not intended to be exhaustive or to limit the invention to the precise forms disclosed, and obviously many modifications, embodiments, and variations are possible in lights of the above teaching. It is intended that the scope of the invention be defined by the Claims appended hereto and their equivalents.

We claim:

1. An apparatus for processing a substrate in a process chamber, comprising:
one or more gas supply sources;
a gas manifold valve cluster proximate to the process chamber comprising a gas valve for each gas; and
a chamber lid gas supply line extending from the gas manifold valve cluster to a gas distribution device wherein the chamber lid gas supply line length and volume are minimized.

2. The apparatus of claim 1 wherein said gas manifold valve cluster is mounted on the outside of the apparatus.

3. The apparatus of claim 1 wherein said gas manifold valve cluster is coupled to said chamber lid gas supply line by a connection point comprising a seal and being adapted to detachably engage a lid of said apparatus.

4. An deposition apparatus for processing a substrate, comprising:
a process chamber housing a wafer support for holding a substrate;
a wafer transfer region where the substrate is conveyed by a transfer device through an opening in a wall of the process chamber and onto the wafer support;
a gas distribution device positioned above the substrate;
a baffle ring formed within the apparatus and encircling the wafer support and having a plurality of apertures formed therein, said baffle ring being configured to separate a reaction zone from an exhaust region;
a gas manifold valve cluster positioned proximate and outside of said process chamber and comprising a gas valve for each gas and a chamber lid gas supply line extending from said gas manifold valve cluster to the gas distribution device; and
the wafer support being movable in the vertical direction toward the gas distribution device to raise the substrate above the level of the wafer transfer region and opening in the wall of the process chamber, and said wafer support cooperates with the baffle ring to define the reaction zone having reduced volume.

5. The deposition apparatus of claim 4 wherein said gas manifold valve cluster is mounted on the outside of the apparatus.

6. The deposition apparatus of claim 4 wherein said apparatus further comprises a chamber lid assembly, and the gas manifold valve cluster is coupled to said chamber lid gas supply line by a connection point comprising a seal and being detachable from said chamber lid assembly to permit opening of said lid.

7. The deposition apparatus of claim 4 wherein the baffle ring is comprised of an upper baffle ring and a lower baffle ring, and said plurality of apertures are formed in said upper baffle ring.

8. The deposition apparatus of claim 4 further comprising: a gas exhaust plenum communicating with said apertures in said baffle ring to exhaust gases from the reaction zone.

9. The deposition apparatus of claim 8 wherein said gas exhaust plenum encircles the substantial circumference of the baffle ring and is configured to exhaust gases from the reaction zone over substantially 360 degrees.

10. An ALD deposition apparatus for processing a wafer, comprising:
a process chamber housing a wafer support;
an injector for conveying gases to the wafer;
a baffle ring encircling the wafer support, said wafer support, injector and baffle ring defining a reaction zone where the wafer is processed, said reaction zone being isolated from a region where the wafer is moved in and out of the apparatus;
a gas manifold valve cluster positioned proximate and outside of said deposition apparatus and comprising a gas valve for each gas and a chamber lid gas supply line extending from said gas manifold valve cluster to the injector; and
a gas exhaust plenum encircling the baffle ring and in fluid communication with apertures formed in the baffle ring, said gas exhaust plenum being configured to exhaust gases from the reaction zone over substantially 360 degrees.
